(19) United States
(12) Patent Application Publication
(10) Pub. No.: US 2019/0352772 A1
(43) Pub. Date: Nov. 21, 2019

(54) DEPOSITION PREVENTION PLATE AND METHOD FOR MANUFACTURING THE SAME, METHOD FOR RECYCLING MATERIAL, AND THIN FILM DEPOSITION APPARATUS

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Peng XU, Beijing (CN); Shengkai PAN, Beijing (CN); Yongkang QIAO, Beijing (CN); Jie LIU, Beijing (CN)

(21) Appl. No.: 15/779,231

(22) PCT Filed: Oct. 13, 2017
(86) PCT No.: PCT/CN2017/106116

§ 371 Date: May 25, 2018

(30) Foreign Application Priority Data
Apr. 18, 2017 (CN) 201710252592.X

(51) Int. Cl. C23C 14/56; C23C 14/24

(52) U.S. Cl. CPC C23C 14/564; C23C 14/24

(57) ABSTRACT

The present disclosure relates to a deposition prevention plate and a method for manufacturing the same, a method for recycling materials, and a thin film deposition apparatus. The deposition prevention plate includes a substrate, and a carrier layer on the substrate for carrying a plating material, wherein the carrier layer can be peeled off from the substrate. By forming a peelable carrier layer on the substrate, the cleaning process of the deposition prevention plate can be simplified, thereby saving the cleaning cost of the deposition prevention plate. In addition, by recycling and reusing the plating material in a method such as distillation, filtration or physical separation, the utilization of the plating material can be further improved.

### CROSS REFERENCE TO RELATED APPLICATIONS

This patent application is a National Stage Entry of PCT/CN2017/106116 filed on Oct. 13, 2017, which claims the benefit and priority of Chinese Patent Application No. 201710252592.X filed on Apr. 18, 2017, the disclosures of which are incorporated herein by reference in their entirety as a part of the present application.

### BACKGROUND

The present disclosure relates to the field of thin film deposition, and particularly, to a deposition prevention plate and a method for manufacturing the same, a method for recycling materials, and a thin film deposition apparatus.

In a thin film deposition apparatus using a physical vapor deposition method, a plating material from a plating material source is deposited on an inner wall of a reaction chamber, in addition to a desired region (for example, a substrate). When the thickness of the formed film reaches a certain level, the film is peeled off from the inner wall. In order to prevent the occurrence of above phenomenon, it is necessary to cover the inner wall of the reaction chamber with a deposition prevention plate. When the thickness of the film formed on the deposition prevention plate is accumulated to a certain level, the deposition prevention plate is subjected to maintenances such as disassembly, replacement, and cleaning. However, the maintenance works reduce the production efficiency and increase the cost.

### BRIEF DESCRIPTION

The embodiments of the present disclosure provide a deposition prevention plate and a method for manufacturing the same, a method for recycling materials, and a thin film deposition apparatus.

A first aspect of the present disclosure provides a deposition prevention plate, including a substrate, and a carrier layer on the substrate for carrying a plating material, wherein the carrier layer can be peeled off from the substrate.

In one embodiment, a material of the carrier layer includes organics.

In one embodiment, the organics include rubber.

In one embodiment, the carrier layer has a dense and uniform structure.

In one embodiment, the plating material includes organics.

A second aspect of the present disclosure provides a thin film deposition apparatus, including any of the deposition prevention plate described in the first aspect of the present disclosure.

A third aspect of the present disclosure provides a method for manufacturing a deposition prevention plate, including the steps of providing a substrate, and forming a carrier layer on the substrate for carrying a plating material, wherein the carrier layer can be peeled off from the substrate.

In one embodiment, a material of the carrier layer includes organics, forming the carrier layer on the substrate includes coating a solution containing the organics on a surface of the substrate, and heating the substrate to evaporate a solvent in the solution.

In one embodiment, the organics include rubber, and the solution includes inorganic or organic glue.

A fourth aspect of the present disclosure provides a method for recycling materials, the method is used for recycling the plating material adhered to the carrier layer of any of the deposition prevention plate described in the first aspect of the present disclosure, including the steps of peeling the carrier layer off from the deposition prevention plate, and processing the carrier layer to recycle the plating material.

In one embodiment, the processing includes immersing the carrier layer into a solvent capable of dissolving the plating material to form a solution in which the plating material is dissolved, and distilling the solution to obtain the plating material.

In one embodiment, a material of the carrier layer and the plating material both include organics, and the material of the carrier layer has a different boiling point than the plating material.

In one embodiment, the material of the carrier layer includes rubber, and the solvent includes cyclohexanone, butyl acetate, or butanone.

In one embodiment, the processing includes immersing the carrier layer into a solvent that dissolves the carrier layer only to form a solution, and filtering the solution to obtain the plating material.

In one embodiment, the material of the carrier layer includes rubber, and the solvent includes acetone.

In one embodiment, the processing includes physically separating the plating material from the carrier layer.

### BRIEF DESCRIPTION OF THE DRAWINGS

The drawings described herein are for illustrative purpose only of selected embodiments rather than any possible implementation, and they are not intended to limit the scope of this disclosure, in which:

FIG. 1 schematically illustrates a cross-sectional view of an exemplary deposition prevention plate according to an embodiment of the present disclosure;

FIG. 2 schematically illustrates a cross-sectional view of an exemplary thin film deposition apparatus according to an embodiment of the present disclosure;

FIG. 3 schematically illustrates a flowchart of a method for manufacturing a deposition prevention plate according to an embodiment of the present disclosure; and

FIG. 4 schematically illustrates a flowchart of a method for recycling materials.

Corresponding reference numerals indicate corresponding parts or features throughout the views of those drawings.

### DETAILED DESCRIPTION

Firstly, it should be noted that unless additionally and explicitly pointed out in the context, the singular form of the words used herein and in the appended claims includes the plural form, and vice versa. Thus, when a word is mentioned in the singular form, it usually includes the plural form. Similarly, the words “include” and “comprise” will be interpreted as inclusive rather than exclusive. Likewise, the terms “comprise” and “or” should be interpreted as inclusive unless the interpretation is explicitly prohibited herein. Where the term “example” is used herein, and particularly following a group of terms, it is merely exemplary and illustrative and should not be considered as exclusive or extensive.

In addition, in the drawings, the thickness and area of each layer are exaggerated for clarity. It should be understood that the orientation or position relationship indicated by the terms “longitudinal”, “radial”, “upper”, “lower”, “front”, “rear”, “left”, “right”, “vertical”, “horizontal”, “top”, “bottom”, “in”, “out” and the like are those illustrated based on the orientation or position relationship shown in the drawings. They are just used to facilitate and simplify the description of the embodiments of the present disclosure, rather than indicating or implying that any mentioned component must have a particular orientation, or be constructed or operated in a particular orientation, and hence cannot be understood as limitations to the present disclosure. In addition, when an element or layer is referred to as being “on” another element or layer, it may be directly located on the another element or layer, or there may be an intermediate element or layer; similarly, when an element or layer is referred to as being “under” another element or layer, it may be directly located under the another element or layer, or there may be at least one intermediate element or layer, and when an element or layer is referred to as being “between” two elements or layers, it may be an only element or layer between the two elements or layers, or there may be more than one intermediate element or layer.

Exemplary embodiments are now described more fully with reference to the drawings.

FIG. 1 schematically illustrates a cross-sectional view of an exemplary deposition prevention plate 10 according to an embodiment of the present disclosure. As illustrated in FIG. 1, the deposition prevention plate 10 may include a substrate 101 and a carrier layer 102 on the substrate 101 for carrying a plating material, the carrier layer 102 can be peeled off from the substrate 101. When it is necessary to clean the deposition prevention plate 10, it only needs to peel the carrier layer 102 off from the substrate 101. For example, the cleaning of the deposition prevention plate may be accomplished by tearing.

As mentioned above, when it is necessary to clean the deposition prevention plate, it is only necessary to peel the carrier layer off from the substrate to accomplish the cleaning, and it is unnecessary to use any complex chemical or physical cleaning method. This cleaning method can reduce the damage to the deposition prevention plate itself and improve the service life of the deposition prevention plate. In addition, since the cleaning method of the deposition prevention plate is much simpler and faster, it does not need to be performed offsite. In practical applications, this can reduce the dependence of the additional backup deposition prevention plate when it needs to maintain the deposition prevention plat and further save the cost.

The embodiment of the present disclosure has no particular limitation to the material of the carrier layer 102, as long as the carrier layer 102 made of this material can be easily peeled off from the substrate 101 and is thermally stable at the deposition temperature of the plating material. Optionally, in order to reduce the potential impact on the atmosphere within the reaction chamber, the material of the carrier layer 102 is selected so that it does not generate additional gas during plating. In one exemplary embodiment, the material of the carrier layer 102 may include organics, including but not limited to rubber.

In one exemplary embodiment, the carrier layer 102 may have a dense and uniform structure and can completely cover the substrate 101, so as to effectively prevent the surface of the substrate 101 from being in contact with the plating material.

In one exemplary embodiment, the carrier layer 102 has a thickness of about 30 μm to 100 μm, preferably about 30 μm. It can be understood that those skilled in the art can appropriately select the thickness of the carrier layer 102 upon actual demands.

According to one embodiment of the present disclosure, the plating material may include organics such as an organic light emitting material.

According to an embodiment of the present disclosure, the cleaning operation on the deposition prevention plate is accomplished after the carrier layer is peeled off from the substrate, thereby simplifying the maintenance procedure and reducing the cleaning cost.

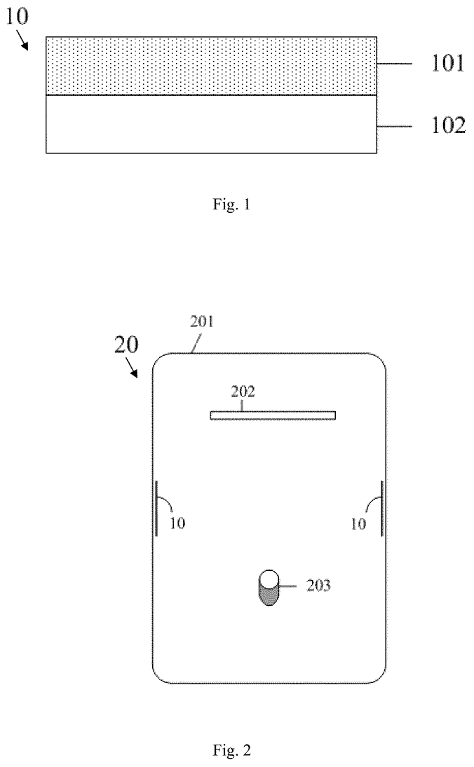

FIG. 2 schematically illustrates a cross-sectional view of an exemplary thin film deposition apparatus 20 according to an embodiment of the present disclosure. As illustrated in FIG. 2, the thin film deposition apparatus 20 may include a reaction chamber 201 and a deposition prevention plate 10 according to the above embodiment of the present disclosure, wherein the deposition prevention plate 10 covers an inner wall of the reaction chamber 201.

In one exemplary embodiment, the thin film deposition apparatus 20 may further include a substrate 202 and a plating material source 203. A plating material from the plating material source 203 is deposited on the deposition prevention plate 10 in addition to the substrate 202. When the thickness of the plating material on the deposition prevention plate 10 is accumulated to a certain level, the deposition prevention plate 10 is disassembled, and then the carrier layer on the surface thereof is peeled off. Since the cleaning method of the deposition prevention plate is much simpler and faster, it does not need to be performed offsite. In practical applications, this can reduce the dependence of the additional backup deposition prevention plate when it needs to maintain the deposition prevention plat and further save the cost.

The embodiments of the present disclosure further provide a method for manufacturing a deposition prevention plate.

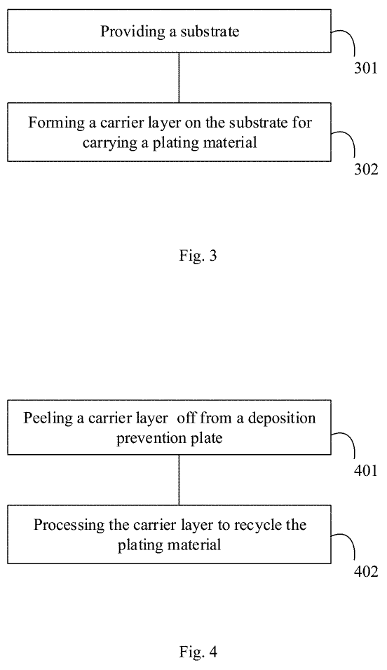

FIG. 3 schematically illustrates a flowchart of a method for manufacturing a deposition prevention plate according to an embodiment of the present disclosure. As illustrated in FIG. 3, the method of the embodiment of the present disclosure includes the steps of:

S301: providing a substrate; and

S302: forming a carrier layer on the substrate for carrying a plating material, wherein the carrier layer can be peeled off from the substrate.

The foregoing steps will be further described below. Since the method is used to manufacture the deposition prevention plate in the foregoing embodiment, explanations of the same components in the above embodiment are applicable herein, which are omitted in the following description.

In S301, the material of the substrate of the deposition prevention plate is not particularly limited, and it may be a metal such as aluminum or aluminum alloy, or any other suitable material. In addition, the embodiment of the present disclosure has no limitation to the shape of the deposition prevention plate, any appropriate shapes can be arbitrarily selected upon actual demands.

In S302, the carrier layer may be formed on the substrate by the following methods: dissolving organics in a solvent to form a solution containing the organics, coating the solution on the surface of the substrate, heating the substrate to evaporate the solvent in the solution, and finally forming the carrier layer containing the organics on the substrate. According to one embodiment of the present disclosure, the solution for forming the carrier layer may be applied by spraying.

According to one exemplary embodiment of the present disclosure, the organics may include rubber, and the rubber is dissolved in a suitable solvent to form a solution. According to one embodiment of the present disclosure, the solution may include inorganic or organic glue.

After the carrier layer for carrying the plating material is formed on the substrate, when it is necessary to clean the deposition prevention plate, it only needs to peel the carrier layer off from the substrate. This cleaning method, the deposition prevention plate does not need to be cleaned offsite, which is more economic and convenient than the conventional cleaning method, thereby saving the cost and increasing the production rate.

OLED display device is applied widely. The OLED display device generally includes organic layers such as a hole injection layer, a hole transport layer, an electron blocking layer, a light emitting layer, a hole blocking layer, an electron transport layer, an electron injection layer, and the like. In the OLED manufacturing process, those organic layers are usually formed using a physical vapor deposition apparatus such as a vacuum evaporation apparatus. Since the organic materials for OLEDs are expensive and the material loss during deposition leads to a high manufacturing cost, there is an urgent need to reasonably recycle and utilize the organic materials.

For this purpose, the embodiments of the present disclosure further provide a method for recycling materials, the method is used for recycling a plating material adhered to a carrier layer of a deposition prevention plate according to the above embodiment of the present disclosure.

FIG. 4 schematically illustrates a flowchart of a method for recycling materials. As illustrated in FIG. 4, the method of the embodiment of the present disclosure may include the steps of:

S401: peeling a carrier layer off from a deposition prevention plate; and

S402: processing the carrier layer to recycle the plating material.

In S401, the carrier layer may be peeled off from the deposition prevention plate by tearing.

In S402, in one exemplary embodiment, the method for processing the carrier layer may include immersing the carrier layer into a solvent capable of dissolving the plating material to form a solution in which the plating material is dissolved; and distilling the solution at a specific temperature to obtain the plating material.

In one exemplary embodiment, the material of the carrier layer may include organics such as rubber. The plating material may include organics such as an organic light emitting material. The solvent may include cyclohexanone, butyl acetate, or butanone.

In one exemplary embodiment, the material of the carrier layer has a different boiling point than the plating material. Therefore, the plating material can be obtained by distillation.

As described above, the plating material obtained by distillation has a high purity, and the obtained plating material can be directly reused in the thin film deposition process, thereby improving the utilization of the plating material.

In S402, in another exemplary embodiment, the method of processing the carrier layer may include immersing the carrier layer into a solvent that dissolves only the carrier layer to form a solution, and then filtering the solution to obtain the plating material.

In one exemplary embodiment, the material of the carrier layer may include organics such as rubber. The plating material may include organics such as an organic light emitting material. The solvent may include acetone.

According to one embodiment of the present disclosure, the carrier layer made of rubber is immersed into an acetone solvent to form a solution, wherein the acetone dissolves only the rubber rather than the plating material, the solution is then filtered to filter out the undissolved plating material, next, the plating material is dried to be finally obtained.

It should be understood that any other solvent, which dissolves the carrier layer while cannot dissolve the plating material, may be applied to the embodiments of the present disclosure.

As described above, the method of obtaining the plating material by filtration improves the utilization of the plating material and achieves a high operability. Since the recycled plating material contains a few of impurities, it needs to be further purified.

In S402, in still another exemplary embodiment, the method for processing the carrier layer may include physically separating the plating material from the carrier layer, for example peeling the plating material from the carrier layer in a physical method such as scraping or rubbing, so as to obtain the plating material.

As described above, the method of obtaining the plating material by physical separation improves the utilization of the plating material and the process is simple. But the recycled plating material has many impurities and needs to be further purified.

It should be noted that the flowchart described in the present disclosure is just one example. There may be many modifications to the flowchart or the steps described therein without departing from the spirit of the present disclosure. For example, the steps may be performed in a different order, or the steps may be added, deleted, or amended.

The foregoing descriptions of the embodiments have been provided for the purposes of illustration and description. It is not intended to be exhaustive or to limit the disclosure. Individual elements or features of a particular embodiment are generally not limited to that particular embodiment, but where appropriate, these elements and features are interchangeable and can be used in a selected embodiment, even if not specifically illustrated or described. The same may also be varied in many ways. Such a variation should not be considered as a departure from the disclosure, and all those modifications are included within the scope of the disclosure.

1. A deposition prevention plate comprising:
a substrate; and
a carrier layer on the substrate for carrying a plating material, wherein the carrier layer can be peeled off from the substrate.

2. The deposition prevention plate according to claim 1, wherein a material of the carrier layer comprises organics.

3. The deposition prevention plate according to claim 2, wherein the organics comprise rubber.

4. The deposition prevention plate according to claim I, wherein the carrier layer has a dense and uniform structure.

5. The deposition prevention plate according to claim 1, wherein the plating material comprises organics.

6. A thin film deposition apparatus comprising the deposition prevention plate according to claim 1.

7. A method for manufacturing a deposition prevention plate, the method comprising the steps of:
providing a substrate; and
forming a carrier layer on the substrate for carrying a plating material, wherein the carrier layer can be peeled off from the substrate.

8. The method according to claim 7, wherein a material of the carrier layer comprises organics, and wherein forming the carrier layer on the substrate comprises coating a solution containing the organics on a surface of the substrate, and heating the substrate to evaporate a solvent in the solution.

9. The method according to claim 8, wherein the organics comprise rubber, and wherein the solution comprises one of inorganic and organic glue.

10. A method for recycling materials, the method for recycling the plating material adhered to the carrier layer of the deposition prevention plate according to claim 1, the method comprising:
peeling the carrier layer off from the deposition prevention plate; and
processing the carrier layer to recycle the plating material.

11. The method according to claim 10, wherein the processing comprises immersing the carrier layer into a solvent capable of dissolving the plating material to form a solution in which the plating material is dissolved, and distilling the solution to obtain the plating material.

12. The method according to claim 16, wherein a material of the carrier layer and the plating material both comprise organics, and wherein the material of the carrier layer has a different boiling point than the plating material.

13. The method according to claim 12, wherein the material of the carrier layer comprises rubber, and wherein the solvent comprises one of cyclohexanone, butyl acetate, and butanone.

14. The method according to claim 10, wherein the processing comprises immersing the carrier layer into a solvent that dissolves only the carrier layer to form a solution, and filtering the solution to obtain the plating material.

15. The method according to claim 14, wherein the material of the carrier layer comprises rubber, and wherein the solvent comprises acetone.

16. The method according to claim 11, wherein the solvent further dissolves the carrier layer.

17. The method according to claim 10, wherein the processing comprises physically separating the plating material from the carrier layer.

18. A thin film deposition apparatus comprising the deposition prevention plate according to claim 2.

19. A method for recycling materials, the method for recycling the plating material adhered to the carrier layer of the deposition prevention plate according to claim 2, the method comprising:
peeling the carrier layer off from the deposition prevention plate; and
processing the carrier layer to recycle the plating material.

20. A method for recycling materials, the method for recycling the plating material adhered to the carrier layer of the deposition prevention plate according to claim 3, the method comprising:
peeling the carrier layer off from the deposition prevention plate; and
processing the carrier layer to recycle the plating material.
